(19) United States
(12) Patent Application Publication
(10) Pub. No.: US 2007/0045571 A1
(43) Pub. Date: Mar. 1, 2007

(54) Method for arranging semiconductor wafer to ion-beam in disk-type implantation

(75) Inventor: Hyuk Woo, Nam-gu (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/510,535

(22) Filed: Aug. 24, 2006

(30) Foreign Application Priority Data
Aug. 25, 2005 (KR) 10-2005-0078240

(51) Int. Cl. H01J 37/08

(52) U.S. Cl. 250/492.21

(57) ABSTRACT

Disclosed is a method for arranging a semiconductor wafer in a disk-type ion implantation apparatus and/or process. In the present method, the wafer is arranged to satisfy conditions of A=T and R=W, where T represents an angle between the ion beam and a normal axis to the plane of the wafer, W represents an angle between a projection of the ion beam to the wafer and a notch of the wafer, A represents a vertical tilt angle of the wafer to the ion beam, B represents a horizontal tilt angle of the wafer to the ion beam, and R represents an anticlockwise rotation angle based on the notch.

This application claims the benefit of Korean Application No. 10-2005-0078240, filed on Aug. 25, 2005, which is incorporated by reference herein in its entirety.

### BACKGROUND OF THE INVENTION

1. Field of the Invention

The present invention relates to a semiconductor device manufacturing technology. More specifically, the present invention relates to method for arranging a semiconductor wafer to an ion beam in an implantation process for implanting dopants in the semiconductor wafer.

2. Description of the Related Art

Conventionally, an implantation process involves ionizing impurities, and then forcibly injecting the ionized impurities (i.e., dopants) in a surface of a semiconductor wafer. A sheet resistance (referred to as Rs), which represents an electrical resistance at a surface of a semiconductor wafer, depends greatly on a vertical concentration distribution of dopants as well as their total dose. In addition, the vertical concentration distribution of dopants may be affected by various factors such as an ion size, implantation energy, implanting angles, etc. In the case where the incidence angle in a disk-type implantation process is too low, the uniformity of Rs can deteriorate due to a channeling phenomenon and/or a cone effect.

### SUMMARY OF THE INVENTION

It is, therefore, an object of the present invention to provide a method for appropriately arranging a semiconductor wafer to an ion beam in an implantation process, thus enabling improvement of the sheet resistance and the uniformity thereof.

According to a preferred embodiment of the present invention, a method for arranging a semiconductor wafer in a disk-type ion implantation process comprises arranging the wafer is arranged to satisfy conditions of A=T and R=W, where T represents an angle between the ion beam and a normal axis to the plane of the wafer, W represents an angle between a projection of the ion beam and a notch of the wafer, A represents a vertical tilt angle of the wafer to the ion beam, B represents a horizontal tilt angle of the wafer to the ion beam, and R represents an anticlockwise rotation angle based on the notch.

It is preferable that T is equal to or less than 2 degrees and W is equal to or less than 45 degrees. In addition, it is preferable that the implantation process is performed under an implantation energy of 800 keV or less and a dose of E12˜E14 atoms/cm³.

### BRIEF DESCRIPTION OF DRAWINGS

FIG. 1 is a graph illustrating the relation between a tilt angle of a wafer to an ion beam and a sheet resistance.

FIG. 2 is a schematic view illustrating definitions for a tilt angle T and a twist angle W according to the orientation of a wafer to an ion beam.

FIG. 3 is a schematic view illustrating definitions for a vertical tilt angle, a horizontal tilt angle, and a rotation angle according to the orientation of a wafer to an ion beam.

FIG. 4 is a graph illustrating results of SIMS analysis after implantation process under a vertical tilt angle, a horizontal tilt angle, and a rotation angle of (1.41, −1.41, 0) combination.

FIG. 5 is a graph illustrating variation of sheet resistances according to an ion implantation energy.

### DETAILED DESCRIPTION OF THE INVENTION

Hereinafter, a preferred embodiment according to the present invention will be described in detail, with reference to the following drawings.

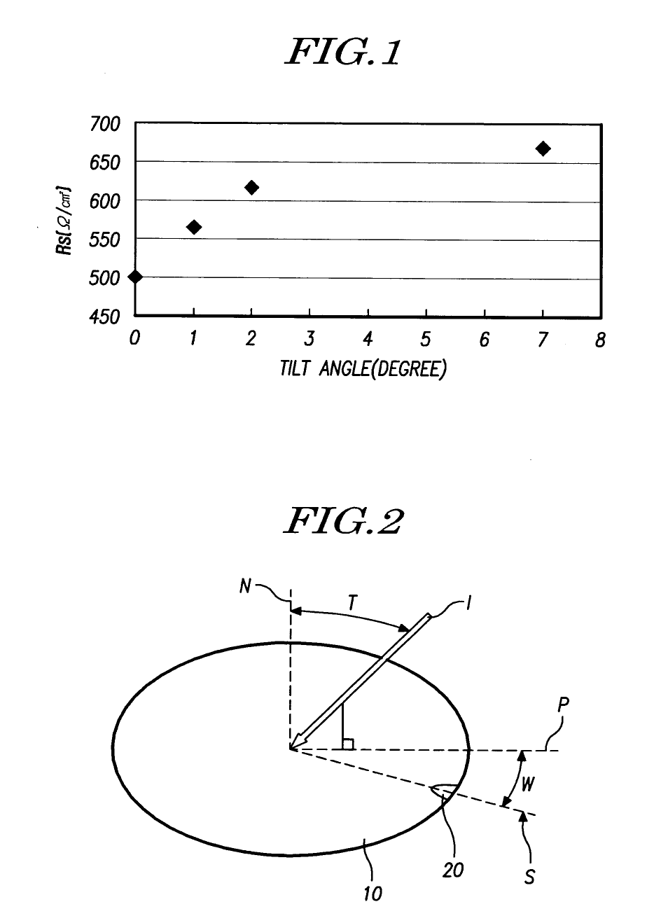

FIG. 1 shows influences of an implanting angle of an ion beam on a sheet resistance Rs of a semiconductor wafer in a disk-type implantation process. Here, a conventional 4-point probe method is used for measurement of the sheet resistance, and an annealing process is performed at a temperature of 1,000° C. for 10 seconds, using rapid thermal processing equipment (e.g., an RTP or RTA furnace). In addition, the ions are implanted under conditions comprising an ion implantation apparatus configured to implant ions into a single wafer mounted on a chuck in the implant chamber of the apparatus, a dopant ion of phosphorus (P), an implantation energy of 360 keV, and a dose of 2.2E13 atoms/cm³.

In general, the sheet resistance after implantation becomes smaller, when the penetration range of dopants becomes deeper. The reasons for the reduction in sheet resistance are that the contribution of the thickness to the sheet resistance increases according to increase of the junction depth, and that the charge mobility increases according to decrease of the dopant concentration. Such phenomena continue until the penetration range reaches up to a certain value. In addition, the penetration range is affected by the implanting angle of the ion beam, as well as the implantation energy.

The reason why the penetration range is affected by the implanting angle is that the channeling changes according to the implanting angle. Specifically, the channeling phenomenon frequently occurs in the <100> direction in a silicon crystal, even though the <111> direction is probably the most frequent channeling direction. Here, the channeling decreases according to an increase of the tilt angle, which is defined as an angle between a normal axis to the plane of a wafer and an ion beam (e.g., in a channeling direction), thus resulting in decrease of the penetration range. Relatively, a twist angle, which is defined as a radial angle relative to a notch of the wafer, is generally considered to have little influence on channeling. FIG. 1, which displays results of measuring sheet resistances with varying the tilt angle in a conventional <100> wafer, shows that the sheet resistance increases according to increase of the tilt angle, and especially, that variation of sheet resistances is large at a relatively low tilt angle. Such results are believed to be due to a relatively low variation of penetration ranges when the tilt angle is relatively distant from the channeling direction.

FIG. 2 shows a schematic view illustrating definitions for a tilt angle T and a twist angle W. As shown in FIG. 2, a tilt angle T represents the angle between a normal axis N to the plane of a wafer 10 and an incidence direction of an ion beam I, and a twist angle W represents the angle between a projection P of the ion beam I to the wafer 10 and an extension line S from a center of the wafer 10 to a center of a notch 20 in the wafer 10.

Referring to FIG. 1, the difference of the sheet resistances at 0 degree and 2 degree of the tilt angle is about 120Ω/cm². However, when the implantation energy is 60 keV, the difference of the sheet resistance is about 46Ω/cm² at the same tilt angles. Thus, the profile variation due to channeling at a low angle is an important factor on the sheet resistance property.

On the other hand, in the disk-type implantation process (e.g., in a single wafer implantation apparatus), the uniformity of the sheet resistance (i.e., Rs uniformity) in a wafer can deteriorate due to the cone effect. The cone effect is caused by variation of the incidence angle of the ion beam. Namely, the surface of the wafer is not perfectly flat, but rather, is slightly curved. As a result, the incidence angle of the ion beam differs slightly as a function of the distance across the wafer (e.g., from the point where projection P intersects the edge of the wafer), even though the ion beam is fixed. Accordingly, when the incidence angle varies from the right to the left side of the wafer, the sheet resistance (which is sensitive to the incidence angle) changes. Thus, the Rs uniformity may deteriorate due to variation of the sheet resistance across the wafer.

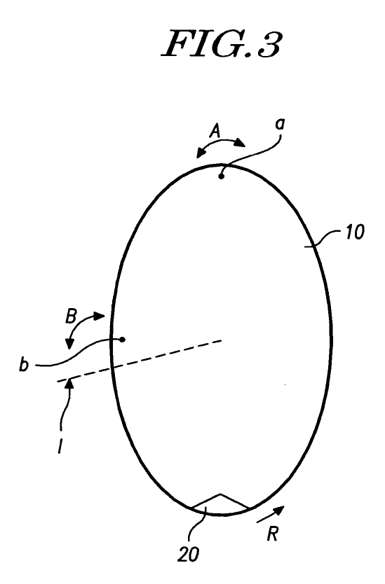

Meanwhile, conventional single-wafer implanters (e.g., a NV-GSD disk-type implanter, produced by Axcelis) may utilize three or more coordinates for mounting a wafer, including a vertical tilt angle A, a horizontal tilt angle B, and a rotational angle R to control an incidence angle of an ion beam, as shown in FIG. 3. The vertical tilt angle A has a positive (+) value when a top portion (referred to as ‘a’) of the wafer 10 tilts toward the incident ion beam I, and it has a negative (−) value in the contrary case. In addition, the horizontal tilt angle B has a positive (+) value when a left portion (referred to as ‘b’) of the wafer 10 tilts toward the incident ion beam I, and it has a negative (−) value in the contrary case. Finally, the rotational angle R has a positive (+) value when the notch 20 pivots counterclockwise on a center axis of the wafer 10.

Even though the tilt angle and the twist angle may be set to fixed values, the cone effect may vary according to combinations of the vertical tilt angle A, the horizontal tilt angle B, and the rotational angle R. In order to obtain an improved Rs uniformity without the cone effect, various angle combinations are explored. Experimental conditions include a dopant of phosphorus, an implantation energy of 360 keV, and a dose of 2.2E13 atoms/cm³. The tilt angles and the twist angle, using various combinations of A, B, and R (as shown in FIG. 3), are shown in Table 1, which also shows the sheet resistance Rs and the Rs uniformity measured at the various angle conditions.

TABLE 1

| | | | | Rs | Rs Uniformity |
|---|---|---|---|---|---|
| | A (degree) | B (degree) | R (degree) | (Ω/cm²) | (%) |
| 1st Mode | 1.41 | −1.41 | 0 | 605.82 | 4.012 |
| 2nd Mode | 1.41 | −1.41 | 0 | 611.06 | 1.409 |
| | −1.41 | 1.41 | | | |
| 3rd Mode | 1.41 | 1.41 | 0 | 613.68 | 1.188 |
| | 1.41 | −1.41 | | | |
| | −1.41 | 1.41 | | | |
| | −1.41 | −1.41 | | | |
| 4th Mode | 2 | 0 | 45 | 622.31 | 0.294 |
| 5th Mode | 0 | 2 | 45 | 623.4 | 4.45 |

As shown in Table 1, even if the implantation is performed under a tilt angle of 2 degree and the twist angle of 45 degree, there can be wide differences in the Rs uniformity according to combinations of A, B, and R. The condition showing the largest cone effect is the combination (A, B, R) of (1.41, −1.41, 0). In this condition, it is observed that the tilt angle in a right side of the wafer becomes close to zero degree, thus the sheet resistance lowers. In addition, among the conditions showing an excellent Rs uniformity is the combination (A, B, R) of (2, 0, 45). As it is known in calculation, the angle between the rotation axis of a wafer and an ion beam becomes smaller, the variation range of the incident angle to the wafer becomes narrower. Among the experimental conditions in Table 1 above, the (2, 0, 45) combination is the closest condition to such calculating condition. Moreover, the second and third examples (2nd mode and 3rd mode in Table 1) show relatively satisfactory Rs uniformities of about 1.41% and 1.12%, respectively.

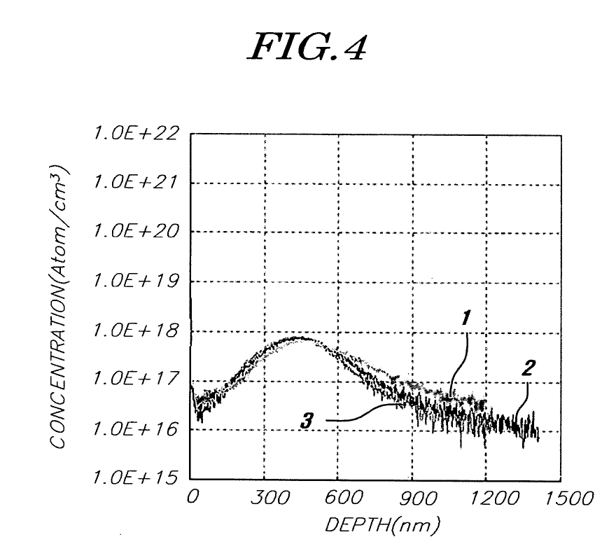

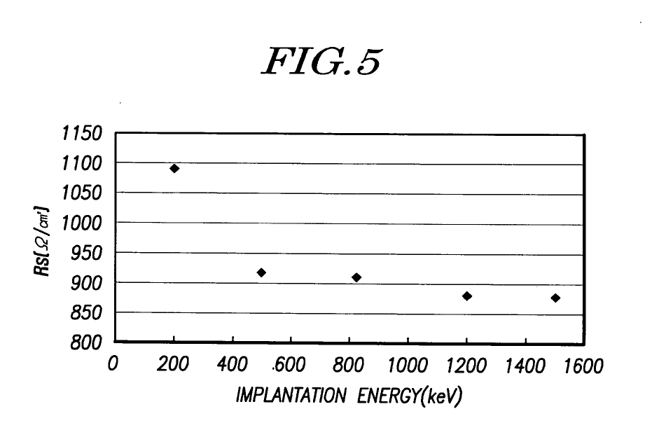

Referring to FIG. 4, it was confirmed, using SIMS (Secondary Ion Mass Spectrometry) analysis, that the relatively low sheet resistance in the first example above (the 1 st mode of Table 1, in which the angles were (1.41, −1.41, 0)) is caused by the differential channeling due to the difference of the incident angles in the wafer. In FIG. 4, the reference numeral 1 indicates the variation curve of the dopant concentration according to the depth, measured in a right side of a wafer in view of the incidence direction of an ion beam. The reference numeral 2 indicates the variation curve of the dopant concentration according to the depth, measured in a center of a wafer. In addition, the reference numeral 3 indicates the variation curve of the dopant concentration according to the depth, measured in a left side of a wafer. As shown in FIG. 4, the channel depth (Rp) varies according to distance across a wafer (e.g., portions of the wafer). Thus, the difference of the sheet resistance results from the difference in the channeling degree. Accordingly, even though the 2nd and 3rd modes can be used, a combination of A, B, and R that minimizes the cone effect is preferable, to prevent deterioration of Rs uniformity due to differential channeling at a low tilt angle.

On the other hand, even though the angle condition contributes to the Rs uniformity, the channel depth can also contribute to the Rs uniformity because a large channel depth results in decrease of the Rs. In order to confirm the extent of an affect of the channel depth on the Rs, a variation of the Rs according to the implantation energy was observed, under implant conditions comprising a dopant of phosphorus and a dose of 1.0E13 atoms/cm³ (as well as constant/fixed tilt and rotational angles). As shown in FIG. 5, if the implantation energy increases under the same dose, the channel depth also changes so that the Rs decreases. However, using an implantation energy higher than 500, 800 or 1200 keV is generally ineffective, because the decrement of Rs is too small.

Furthermore, it was observed that the Rs uniformity is less than 1% under a high dose condition, even under a relatively low implantation energy condition. Under implant conditions comprising ³¹P⁺, 45 keV, 1.5E15 atoms/cm³, and (000) combination, Rs is 78.4Ω/cm² and Rs uniformity is 0.25%. Such result implies that a surface of a wafer partially becomes amorphous, and the differential channeling reduces.

In the disk-type implantation, the Rs uniformity is poor because of the differential channeling by the cone effect under a low angle. In order to overcome such problems, it is preferable to minimize the angle between a rotational axis of a wafer and an ion beam. According to the present invention, a wafer can be arranged in an ion implantation apparatus and/or process using a vertical tilt angle A, a horizontal tilt angle B, and a rotational angle R. The combination A, B, and R is appropriately set so that Rs and Rs uniformity of the wafer can be improved.

While the invention has been shown and described with reference to certain preferred embodiments thereof, it will be understood by those skilled in the art that various changes in form and details may be made therein without departing from the spirit and scope of the invention as defined by the appended claims.

What is claimed:

1. A method for arranging a semiconductor wafer in a disk-type ion implantation process, comprising arranging the wafer to satisfy conditions of A=T and R=W, where T represents an angle between an ion beam and a normal axis to a plane of the wafer, W represents an angle between a projection of the ion beam to the wafer and a notch of the wafer, A represents a vertical tilt angle of the wafer to the ion beam, and R represents an anticlockwise rotation angle based on the notch.

2. The method of claim 1, wherein T is equal to or less than 2 degrees and W is equal to or less than 45 degrees.

3. The method of claim 1, wherein the wafer is further arranged to satisfy a condition of A=B or B=0, where B represents a horizontal tilt angle of the wafer to the ion beam.

4. A method of ion implantation, comprising the method of claim 1, and implanting ions in the wafer.

5. The method of claim 4, wherein the ions are implanted at an implantation energy of 800 keV or less.

6. The method of claim 4, wherein the ions are implanted at a dose of E12˜E14 atoms/cm³.

7. The method of claim 4, wherein the ions are implanted at an implantation energy of 800 keV or less and a dose of E12˜E14 atoms/cm³.

8. The method of claim 4, wherein the implanted ions comprise phosphorus (P).

9. A method for arranging a semiconductor wafer in an ion implantation apparatus, comprising placing the wafer in the apparatus such that an angle between an ion beam generated by the apparatus and a normal axis to a plane of the wafer is about equal to a vertical tilt angle of the wafer to the ion beam, and an angle between a projection of the ion beam to the wafer and a notch of the wafer is about equal to an anticlockwise rotation angle based on the notch.

10. The method of claim 9, wherein the angle between an ion beam and a normal axis to a plane of the wafer is equal to or less than 2 degrees and the angle between the projection of the ion beam to the wafer and the notch is equal to or less than 45 degrees.

11. The method of claim 9, wherein the wafer is placed such that a horizontal tilt angle of the wafer to the ion beam is either substantially zero or about equal to the vertical tilt angle of the wafer to the ion beam.

12. A method of ion implantation, comprising the method of claim 9, and implanting ions in the wafer.

13. The method of claim 12, wherein the ions are implanted at an implantation energy of 800 keV or less.

14. The method of claim 12, wherein the ions are implanted at a dose of E12˜E14 atoms/cm³.

15. The method of claim 12, wherein the ions are implanted at an implantation energy of 800 keV or less and a dose of E12˜E14 atoms/cm³.

16. The method of claim 12, wherein the implanted ions comprise phosphorus (P).
